(19) United States
(12) Patent Application Publication
(10) Pub. No.: US 2025/0275122 A1
(43) Pub. Date: Aug. 28, 2025

(54) SEMICONDUCTOR DEVICE AND METHOD OF FABRICATING THE SAME

(71) Applicant: Samsung Electronics Co., Ltd., Suwon-si (KR)

(72) Inventors: Yanghee LEE, Suwon-si (KR); Sujeong KIM, Suwon-si (KR); Hyukmin KIM, Suwon-si (KR); Changmin PARK, Suwon-si (KR); Jin-Woo BAE, Suwon-si (KR); Woohyuk JANG, Suwon-si (KR); Jin Soon HAN, Suwon-si (KR); Hyunsu HWANG, Suwon-si (KR)

(73) Assignee: Samsung Electronics Co., Ltd., Suwon-si (KR)

(21) Appl. No.: 18/918,612

(22) Filed: Oct. 17, 2024

(30) Foreign Application Priority Data
Feb. 23, 2024 (KR) 10-2024-0026473

(51) Int. Cl. H10B 12/00

(52) U.S. Cl. CPC H10B 12/482; H10B 12/315; H10B 12/485

(57) ABSTRACT

Disclosed are semiconductor devices and their fabrication methods. The semiconductor device comprises device isolation patterns in a substrate and defining active sections extending in a first direction, a first impurity region on a central region of the active section, second impurity regions on edges of the active section, a bit line connected to the first impurity region and running in a second direction across the active sections, a bit-line capping pattern on the bit line, a storage node contact in contact with each of the second impurity regions, a diffusion barrier pattern covering a top surface of the bit-line capping pattern and a top surface of the storage node contact, and a landing pad on the diffusion barrier pattern. A top surface of the diffusion barrier pattern is flat.

### CROSS-REFERENCE TO RELATED APPLICATION

This U.S. nonprovisional application claims priority under 35 U.S.C. § 119 to Korean Patent Application No. 10-2024-0026473 filed on Feb. 23, 2024 in the Korean Intellectual Property Office, the disclosure of which is hereby incorporated by reference in its entirety.

### BACKGROUND

The present inventive concepts relate to semiconductor devices and methods of fabricating the same.

Semiconductor devices have an important role in the electronic industry because of their small size, multi-functionality, and/or low fabrication cost. Semiconductor devices may be categorized as any one of semiconductor memory devices storing logic data, semiconductor logic devices processing operations of logic data, and hybrid semiconductor devices having both memory and logic elements.

Recently, high speed and low consumption of electronic products require that semiconductor devices embedded in the electronic products should have high operating speed and/or lower operating voltage. For satisfying the above demands, semiconductor devices have been more highly integrated. The high integration of semiconductor devices may cause reduced reliability of the semiconductor devices. Therefore, various studies have been conducted for enhancing the reliability of semiconductor devices.

### SUMMARY

Some example embodiments of the present inventive concepts provide semiconductor devices with increased reliability.

Some example embodiments of the present inventive concepts provide methods of fabricating a semiconductor device with increased reliability.

The example embodiments of the present inventive concepts is not limited to the mentioned above, and other example embodiments which have not been mentioned above will be clearly understood to those skilled in the art from the following description.

According to an example embodiment of the present inventive concepts, a semiconductor device includes a plurality of device isolation patterns in a substrate, the device isolation patterns defining a plurality of active sections, the active patterns extending in a first direction, a first impurity region on a central region of each of the active sections, a plurality of second impurity regions on edges of each of the active sections, a bit line connected to the first impurity region, the bit line running in a second direction across the active sections, the second direction intersecting the first direction, a bit-line capping pattern on the bit line, a storage node contact in contact with each of the second impurity regions, a diffusion barrier pattern covering a top surface of the bit-line capping pattern and a top surface of the storage node contact; and a landing pad on the diffusion barrier pattern, wherein a top surface of the diffusion barrier pattern is flat.

According to an example embodiment of the present inventive concepts, a semiconductor device includes a plurality of device isolation patterns in a substrate, the device isolation patterns defining a plurality of active sections, the active sections extending in a first direction, a plurality of word lines in the substrate, the word lines running in a second direction across the active sections, the second direction intersecting the first direction, a first impurity region on a central region of each of the active sections, a plurality of second impurity regions on edges of each of the active sections, a bit line connected to the first impurity region, the bit line running in the second direction across the word lines, a bit-line capping pattern on the bit line, a bit-line spacer covering a sidewall of the bit line and a sidewall of the bit-line capping pattern, a storage node contact in contact with each of the second impurity regions, a diffusion barrier pattern covering a top surface of the bit-line capping pattern, a top surface of the storage node contact, and a top surface and a sidewall of the bit-line spacer, and a landing pad on the diffusion barrier pattern, wherein the diffusion barrier pattern has a first thickness on the top surface of the bit-line capping pattern and a second thickness on the sidewall of the bit-line capping pattern, and the second thickness is greater than the first thickness.

According to an example embodiment of the present inventive concepts, a semiconductor device includes a plurality of device isolation patterns in a substrate, the device isolation patterns defining a plurality of active sections, the active sections extending in a first direction, a first impurity region on a central region of each of the active sections, a plurality of second impurity regions on edges of each of the active sections, a bit line connected to the first impurity region, the bit line running in a second direction across the active sections, the second direction intersecting the first direction, a bit-line capping pattern on the bit line, a bit-line spacer covering a sidewall of the bit line and a sidewall of the bit-line capping pattern, a storage node contact in contact with each of the second impurity regions, a first sub-diffusion barrier pattern covering a top surface of the storage node contact and a sidewall of the bit-line spacer, a second sub-diffusion barrier pattern covering the first sub-diffusion barrier pattern and a top surface of the bit-line capping pattern, and a landing pad on the first and second sub-diffusion barrier patterns.

According to an example embodiment of the present inventive concepts, a method of fabricating a semiconductor device includes forming in a substrate a plurality of device isolation patterns to define active sections, forming a plurality of first impurity regions and a plurality of second impurity regions on the active sections, forming a plurality of bit lines on the substrate and a plurality of bit-line capping patterns on the bit lines, the bit lines running across the active sections and being in contact with corresponding ones of the first impurity regions, forming a plurality of bit-line spacers to cover sidewalls of the bit lines and sidewalls of the bit-line capping patterns, forming storage node contacts in contact with the second impurity regions between adjacent pairs of the bit lines, respectively, planarizing top surfaces of the bit lines and top surfaces of the bit-line spacers, removing upper portions of the storage node contacts to expose upper sidewalls of the bit-line spacers, forming a first diffusion barrier layer on a front surface of the substrate, removing the first diffusion barrier layer on the bit-line capping patterns and the bit-line spacers and forming a first sub-diffusion barrier pattern on sidewalls of the bit-line spacers, forming a second diffusion barrier layer on the first sub-diffusion barrier pattern, the bit-line capping patterns, and the bit-line spacer, forming a landing pad layer on the second diffusion barrier layer, and patterning the landing pad layer, the first sub-diffusion barrier pattern, and the second diffusion barrier layer to expose the upper sidewalls of the bit-line spacers and upper sidewalls of the bit-line capping patterns and to form a diffusion barrier pattern and a landing pad.

### BRIEF DESCRIPTION OF DRAWINGS

FIG. 1 illustrates a plan view showing a semiconductor device according to an example embodiment of the present inventive concepts.

FIG. 2 illustrates a cross-sectional view taken along lines A-A′ and B-B′ of FIG. 1.

FIGS. 3A and 3B illustrate enlarged views showing section P1 of FIG. 2.

FIGS. 4A to 41 illustrate cross-sectional views showing a method of fabricating the semiconductor device of FIG. 2, according to an example embodiment.

FIG. 5 illustrates a cross-sectional view taken along lines A-A′ and B-B′ of FIG. 1, according to an example embodiment.

FIG. 6 illustrates an enlarged view showing section P2 of FIG. 5.

FIG. 7 illustrates a cross-sectional view taken along lines A-A′ and B-B′ of FIG. 1, according to an example embodiment.

FIG. 8 illustrates a cross-sectional view taken along lines A-A′ and B-B′ of FIG. 1, according to an example embodiment.

### DETAILED DESCRIPTION

Some example embodiments of the present inventive concepts will now be described in detail with reference to the accompanying drawings to aid in clearly explaining the present inventive concepts.

While the term “same,” “equal” or “identical” is used in description of example embodiments, it should be understood that some imprecisions may exist. Thus, when one element is referred to as being the same as another element, it should be understood that an element or a value is the same as another element within a desired manufacturing or operational tolerance range (e.g., ±10%).

When the term “about,” “substantially” or “approximately” is used in this specification in connection with a numerical value, it is intended that the associated numerical value includes a manufacturing or operational tolerance (e.g., ±10%) around the stated numerical value. Moreover, when the word “about,” “substantially” or “approximately” is used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes.

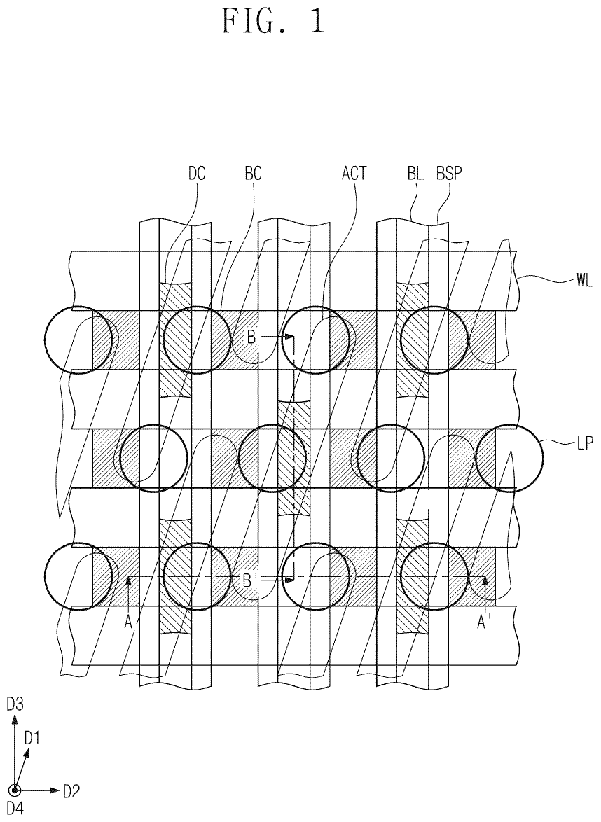

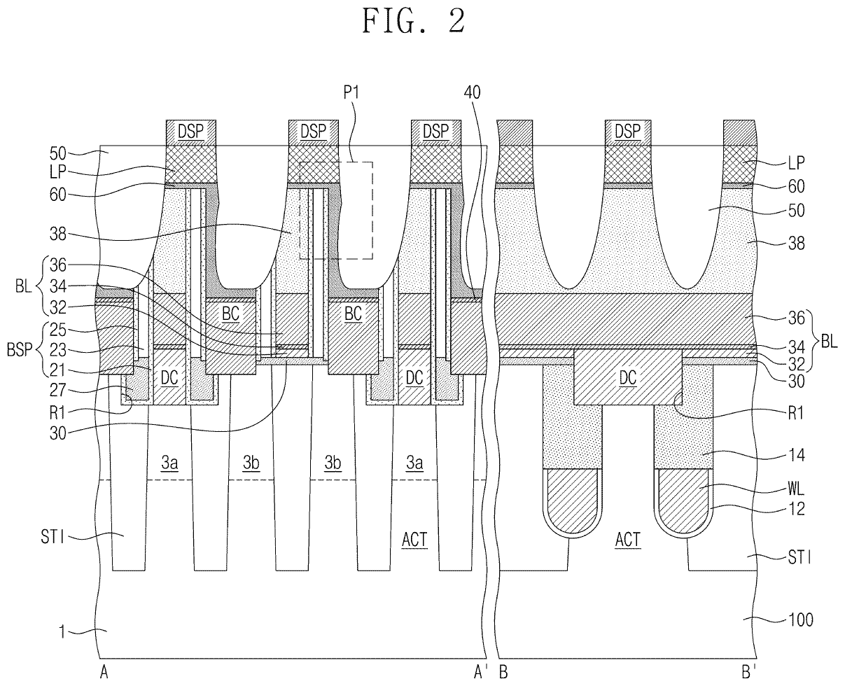

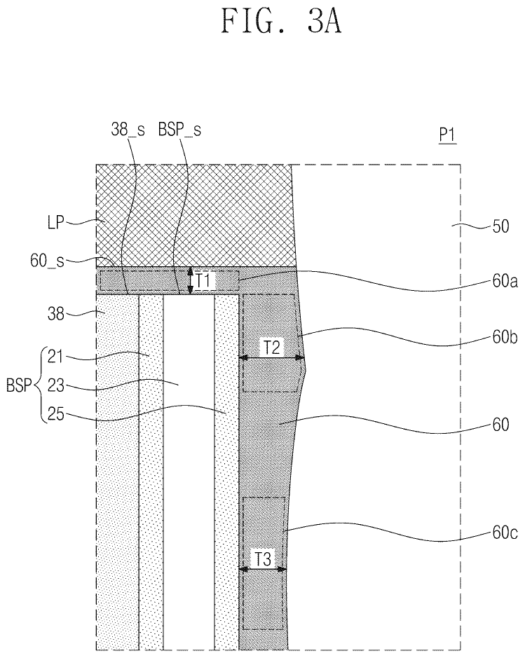

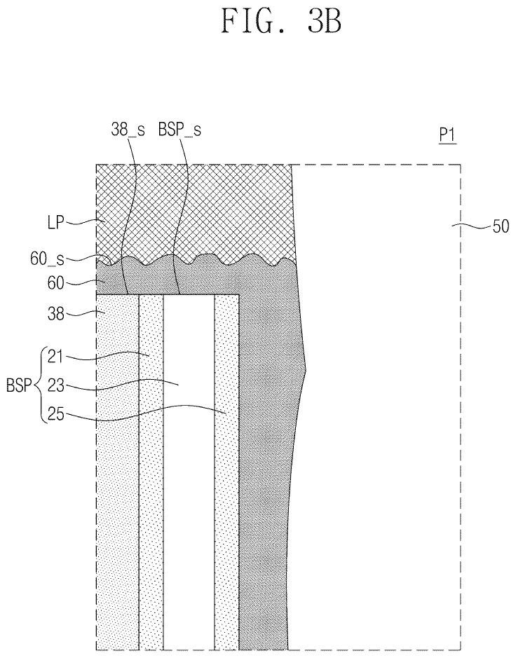

FIG. 1 illustrates a plan view showing a semiconductor device according to an example embodiment of the present inventive concepts. FIG. 2 illustrates a cross-sectional view taken along lines A-A′ and B-B′ of FIG. 1. FIGS. 3A and 3B illustrate enlarged views showing section P1 of FIG. 2.

Referring to FIGS. 1 and 2, a substrate 1 may be provided. For example, the substrate 1 may be a monocrystalline silicon substrate or a silicon-on-Insulator (SOI) substrate. The substrate 1 may be provided therein with device isolation patterns STI that define active sections ACT. Each of the active sections ACT may have an isolated shape. Each of the active sections ACT may have a bar shape elongated along a first direction D1 in a plan view. When viewed in plan, the active sections ACT may respectively correspond to portions of the substrate 1 that are surrounded by the device isolation patterns STI. The active sections ACT may be arranged in parallel to each other in the first direction D1 such that one of the active sections ACT may have an end portion adjacent to a central portion of a neighboring one of the active sections ACT.

The substrate 1 may include a semiconductor material. For example, the substrate 1 may be a silicon substrate, a germanium substrate, or a silicon-germanium substrate. The device isolation patterns STI may include one or more of oxide (e.g., silicon oxide), nitride (e.g., silicon nitride), and oxynitride (e.g., silicon oxynitride).

Word lines WL may run across the active sections ACT. The word lines WL may be disposed in grooves formed in the device isolation patterns STI and the active sections ACT. The word lines WL may extend in a second direction D2 that intersects the first direction D1 and may be parallel to each other in a third direction D3 that intersects the first direction D1 and the second direction D2. The word lines WL may be formed of a conductive material. A gate dielectric layer 12 may be disposed between each of the word lines WL and an inner surface of each groove. Although not shown, the grooves may have their bottom surfaces located relatively deeper in the device isolation patterns STI and relatively shallower in the active sections ACT. The gate dielectric layer 12 may include at least one selected from thermal oxide, silicon nitride, silicon oxynitride, and high-k dielectrics. Each of the word lines WL may have a curved bottom surface.

A first impurity region 3a may be disposed in the active section ACT between a pair of word lines WL, and a pair of second impurity regions 3b may be disposed in opposite edge portions of the active section ACT. The first and second impurity regions 3a and 3b may be doped with, for example, n-type impurities. A transistor may be constituted by each word line WL and an adjacent pair of first and second impurity regions 3a and 3b. As the word lines WL are disposed in the grooves, each of the word lines WL may have thereunder a channel region whose channel length becomes increased within a limited planar area. Accordingly, short-channel effects may be minimized. The present inventive concepts, however, are not limited thereto, and the arrangement of the word lines WL may be variously changed.

The word lines WL may have their top surfaces lower than those of the active sections ACT. Word-line capping patterns 14 may be correspondingly disposed on the word lines WL, respectively. The word-line capping pattern 14 may have a linear shape that extends along a longitudinal direction of a corresponding word line WL, and may cover an entire top surface of the word line WL. The grooves may have inner spaces not occupied by the word lines WL, and the word-line capping patterns 14 may fill the unoccupied inner spaces of the grooves. The word-line capping patterns 14 may be formed of, for example, a silicon nitride layer.

An interlayer dielectric pattern 30 may be disposed on the substrate 1. The interlayer dielectric pattern 30 may be formed of a single layer or multiple layers including at least one selected from a silicon oxide layer, a silicon nitride layer, and a silicon oxynitride layer. The interlayer dielectric pattern 30 may be formed to have island shapes that are spaced apart from each other when viewed in plan. In some example embodiments, the interlayer dielectric pattern 30 may be formed to have a mesh shape when viewed in plan. The interlayer dielectric pattern 30 may be formed to cover end portions of two adjacent active sections ACT.

Upper portions of the substrate 1, the device isolation patterns STI, and the word-line capping patterns 14 may be partially recessed to form a first recess R1. The first recess R1 may have a mesh shape when viewed in plan. The first recess R1 may have a sidewall aligned with that of the interlayer dielectric pattern 30.

Bit lines BL may be disposed on the interlayer dielectric pattern 30. The bit lines BL may run across the word-line capping patterns 14 and the word lines WL. As disclosed in FIG. 1, the bit lines BL may extend in a third direction D3. The bit lines BL may be spaced apart from each other (e.g., parallel to each other) in the second direction D2.

The bit line BL may include a bit-line polysilicon pattern 32, a bit-line diffusion barrier pattern 34, and a bit-line wiring pattern 36 that are sequentially stacked. The bit-line polysilicon pattern 32 may include impurity-doped polysilicon. The bit-line diffusion barrier pattern 34 may include at least one selected from titanium, titanium nitride (TiN), titanium silicon nitride (TiSiN), tantalum, tantalum nitride, and tungsten nitride. The bit-line wiring pattern 36 may include metal, such as tungsten, aluminum, or copper. Bit-line capping patterns 38 may be correspondingly disposed on the bit lines BL. The bit-line capping patterns 38 may be formed of a dielectric material, such as a silicon nitride layer.

A bit-line contact DC may be disposed in the first recess R1 that intersects the bit line BL. The bit-line contact DC may have a top surface at substantially the same level as that of a top surface of the bit-line polysilicon pattern 32. The bit-line contact DC may include at least one selected from impurity-doped polysilicon, impurity-undoped polysilicon, and metallic materials (e.g., Ti, Mo, W, Cu, Al, Ta, Ru, and Ir). When viewed in cross-section taken along line B-B′ as shown in FIG. 2, the bit-line contact DC may have a sidewall in contact with that of the interlayer dielectric pattern 30. As shown in the plan view of FIG. 1, portions of sidewalls of the bit-line contacts DC may be concave. The bit-line contact DC may electrically connect the first impurity region 3a and the bit line BL to each other.

The first recess R1 may have an empty space not occupied by the bit-line contact DC, and a lower buried dielectric pattern 27 may occupy the empty space of the first recess R1. The lower buried dielectric pattern 27 may be formed of a single layer or multiple layers including at least one selected from a silicon oxide layer, a silicon nitride layer, and a silicon oxynitride layer.

Storage node contacts BC may be disposed between a pair of neighboring bit lines BL. The storage node contacts BC may be spaced apart from each other. The storage node contacts BC may include impurity-doped polysilicon or impurity-undoped polysilicon. Differently from that shown, the storage node contacts BC each may have a concave top surface. Between the bit lines BL, more specifically between the storage node contacts BC, a dielectric pattern (not shown) may be disposed.

A bit-line spacer BSP may be interposed between the bit line BL and the storage node contact BC. The bit-line spacer BSP may cover a sidewall of the bit-line contact DC, a sidewall of the bit line BL, and a sidewall of the bit-line capping pattern 38. The bit-line spacer BSP may extend in the third direction D3 along the sidewall of the bit line BL when viewed in plan as shown in FIG. 1.

The bit-line spacer BSP may include first, second, and third sub-spacers 21, 23, and 25 that are sequentially disposed from the sidewall of the bit line BL. The first and third sub-spacers 21 and 25 may include a material having an etch selectivity with respect to the second sub-spacer 23. For example, the first and third sub-spacers 21 and 25 may include silicon nitride. The second sub-spacer 23 may include silicon oxide. In some example embodiments, the second subs-spacer 23 may be an air gap.

The first sub-spacer 21 may downwardly extend to cover the sidewall of the bit-line contact DC. The first sub-spacer 21 may be interposed between the lower buried dielectric pattern 27 and the device isolation pattern STI. As shown in the cross-sectional view taken along line A-A′ of FIG. 2, the bit-line spacer BSP and the bit-line capping pattern 38 each may have a flat top surface. The top surface of the bit-line capping pattern 38 may be coplanar with those of the first, second, and third sub-spacers 21, 23, and 25.

A storage node ohmic layer 40 may be disposed on the storage node contact BC. The storage node ohmic layer 40 may include metal silicide. A diffusion barrier pattern 60 may be disposed on the storage node ohmic layer 40. The diffusion barrier pattern 60 may have a single-layered or multi-layered structure of at least one selected from, for example, titanium, titanium nitride, titanium silicon nitride, tantalum, tantalum nitride, tungsten nitride, molybdenum, and molybdenum nitride.

The diffusion barrier pattern 60 may cover a top surface of the storage node ohmic layer 40 and a sidewall of the third sub-spacer 25. The diffusion barrier pattern 60 may extend to cover the top surface of the bit-line capping pattern 38 and the top surfaces of the first, second, and third sub-spacers 21, 23, and 25.

A landing pad LP may be disposed on the diffusion barrier pattern 60. The landing pad LP may cover the top surface of the bit-line capping pattern 38 and the top surface of the bit-line spacer BSP. The diffusion barrier pattern 60 may be interposed between the bit-line capping pattern 38 and the landing pad LP and between the bit-line spacer BSP and the landing pad LP. The diffusion barrier pattern 60 may electrically connect the storage node contact BC to the landing pad LP. The diffusion barrier pattern 60 may be called a conductive pattern or a pad connection pattern.

A center of the landing pad LP may be shifted in the second direction D2 away from a center of the storage node contact BC. A portion of the bit line BL may vertically overlap the landing pad LP. A portion of a lower end of the landing pad LP may be located at a level higher than that of the top surface of the bit-line capping pattern 38. The landing pad LP may be provided in plural. The landing pad LP may include metal, such as tungsten.

On the storage node contacts BC, a landing pad isolation pattern 50 may be disposed between a pair of adjacent landing pads LP to separate the landing pads LP from each other. Portions of the landing pad isolation pattern 50 may penetrate a portion of the bit-line capping pattern 38. Portions of the landing pad isolation pattern 50 may downwardly extend to contact an upper portion of the second sub-spacer 23. The landing pad isolation pattern 50 may have a single-layered or multi-layered structure of at least one selected from, for example, a silicon nitride layer, a silicon oxide layer, a silicon oxynitride layer, and a porous layer.

A data storage element DSP may be disposed on the landing pads LP. The data storage element DSP may be a capacitor including a bottom electrode, a dielectric layer, and a top electrode. In this case, a semiconductor device may be a dynamic random access memory (DRAM). In some example embodiments, the data storage element DSP may include a magnetic tunnel junction pattern. In some example embodiments, the data storage element DSP may include a phase change material or a variable resistance material.

Referring to FIGS. 2 and 3A, the diffusion barrier pattern 60 may include first, second, and third parts 60a, 60b, and 60c. The first part 60a may cover a top surface BSP_s of the bit-line spacer BSP and a top surface 38_s of the bit-line capping pattern 38. The first part 60a may have a first thickness T1. The second part 60b may cover an upper sidewall of the bit-line spacer BSP and may have a second thickness T2 greater than the first thickness T1. The third part 60c may be disposed beneath the second part 60b and may cover a sidewall of the bit-line spacer BSP. The third part 60c may have a third thickness T3 greater than the first thickness T1 and less than the second thickness T2.

In a semiconductor device according to the present example embodiment, the diffusion barrier pattern 60 may be configured such that the second thickness T2 and the third thickness T3 of the parts 60b and 60c that cover the sidewall of the bit-line spacer BSP are greater than the first thickness T1, and thus a connection between the landing pad LP and the storage node contact BC may be achieved without interruption. Therefore, malfunction of a semiconductor device may be reduced or prevented and reliability of the semiconductor device may be improved.

The top surface BSP_s of the bit-line spacer BSP may be flat, and the top surface 38_s of the bit-line capping pattern 38 may be flat. The top surface BSP_s of the bit-line spacer BSP may be coplanar with the top surface 38_s of the bit-line capping pattern 38. A portion of the diffusion barrier pattern 60 positioned on the bit-line capping pattern 38 and the bit-line spacer BSP may have a top surface 60_s that is flat as shown in FIG. 3A. In some example embodiments, the diffusion barrier pattern 60 positioned on the bit-line capping pattern 38 and the bit-line spacer BSP may have an unevenly structured top surface 60_s as shown in FIG. 3B.

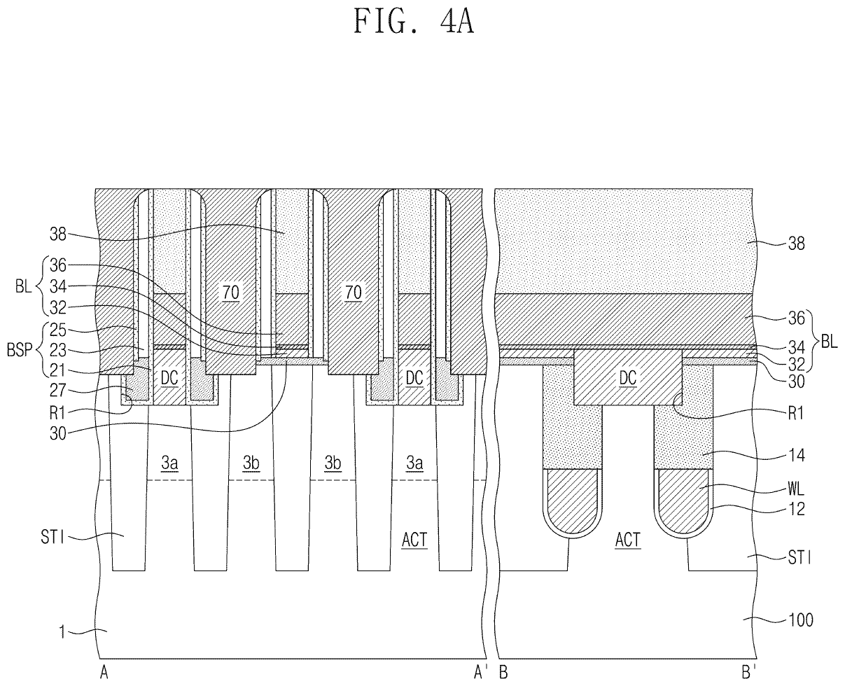

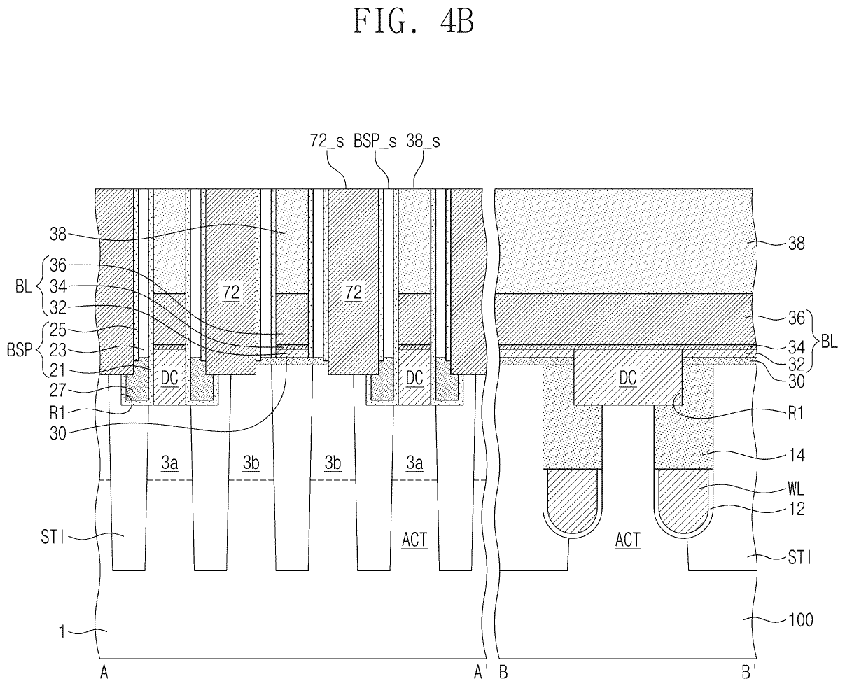

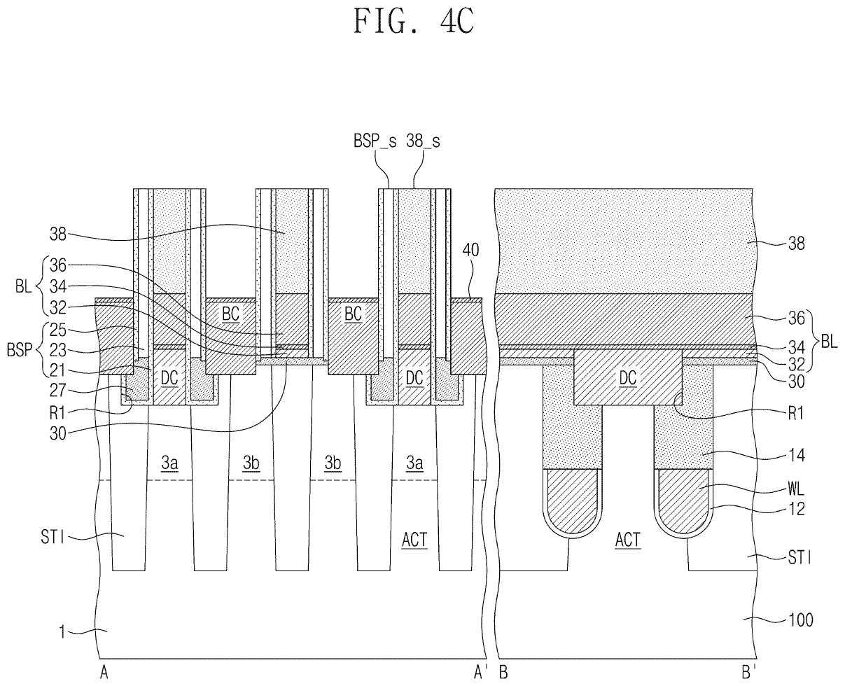

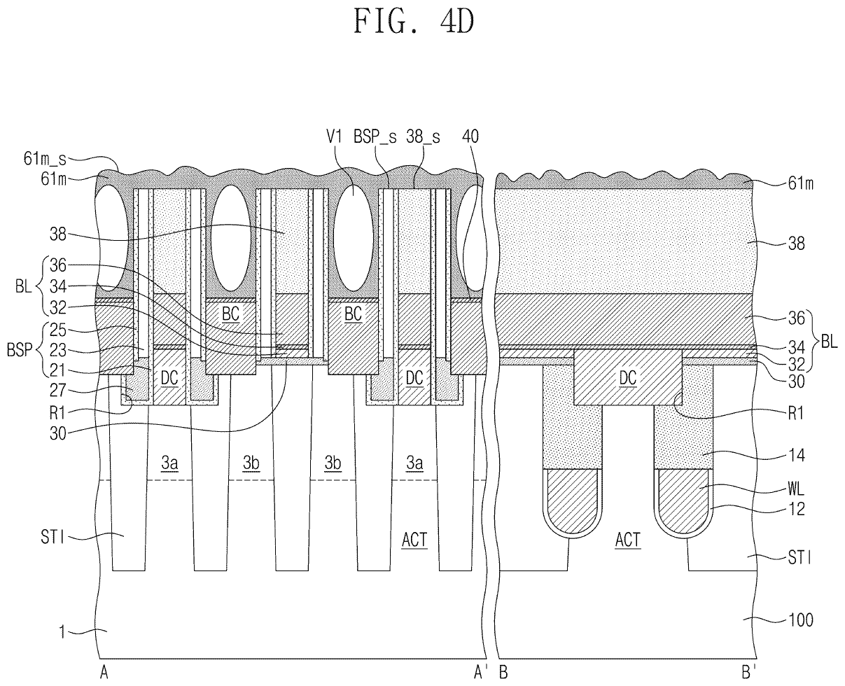

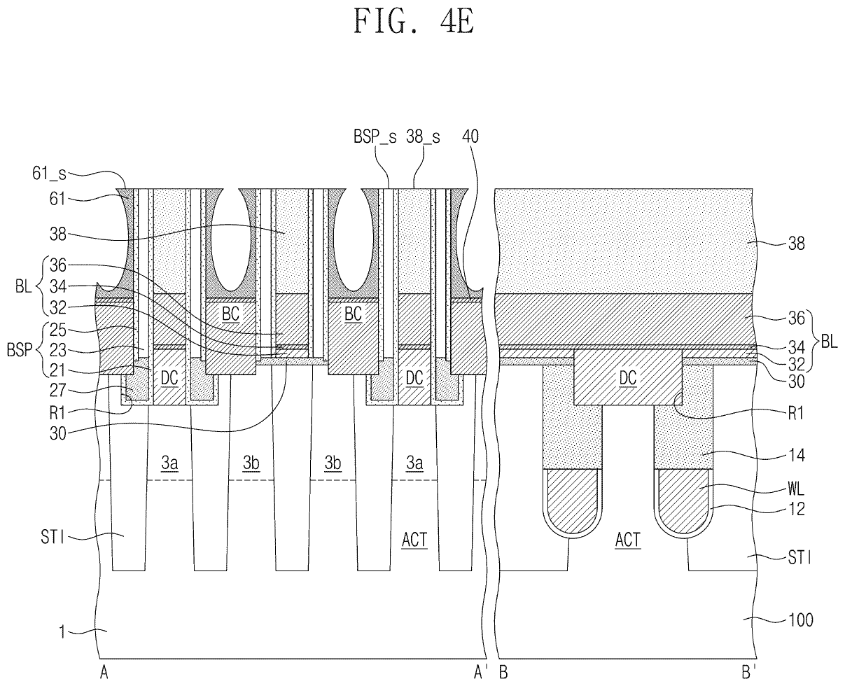

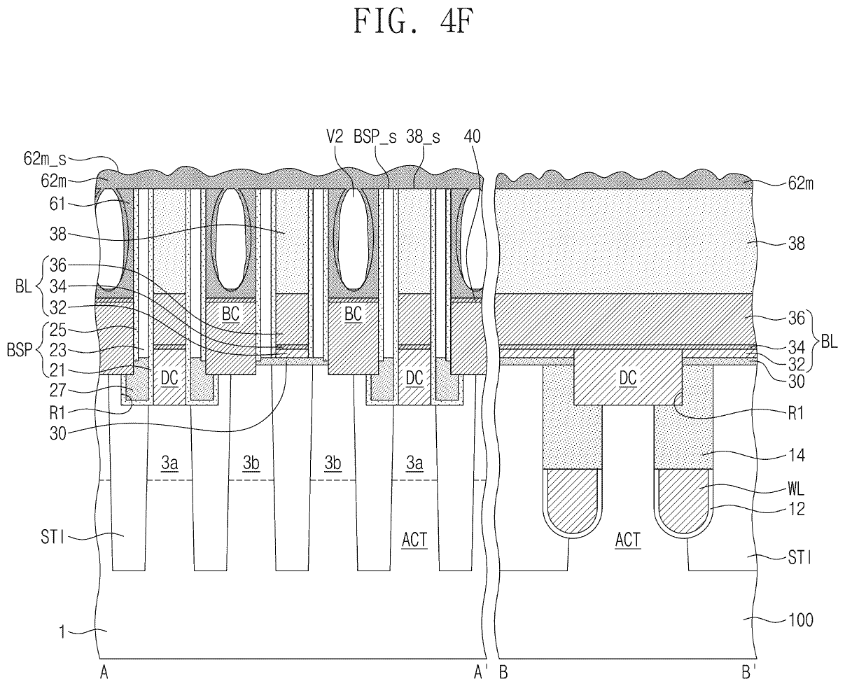

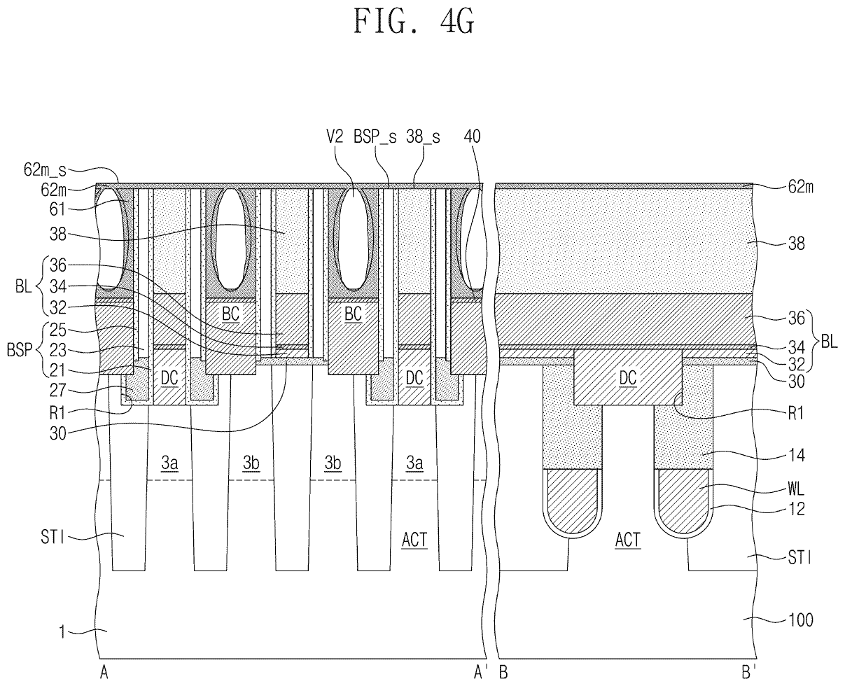

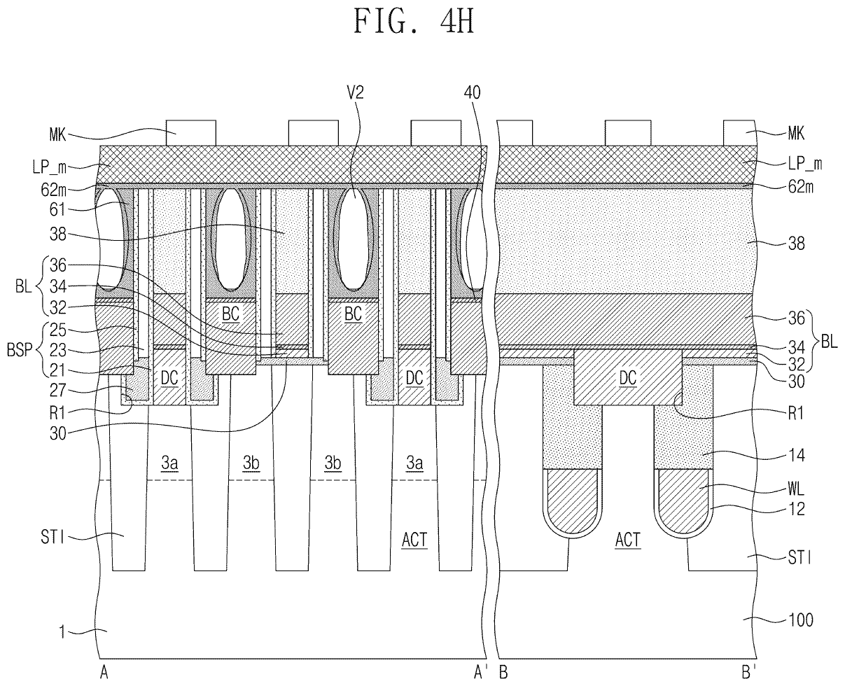

FIGS. 4A to 41 illustrate cross-sectional views showing a method of fabricating the semiconductor device of FIG. 2.

Referring to FIG. 4A, device isolation patterns STI may be formed in a substrate 1 to define active sections ACT. A device isolation trench may be formed in the substrate 1, and the device isolation patterns STI may fill the device isolation trench. The active sections ACT and the device isolation patterns STI may be patterned to form grooves.

Word lines WL may be correspondingly formed in the grooves. A pair of word lines WL may run across the active sections ACT. Before the formation of the word lines WL, a gate dielectric layer 12 may be formed on an inner surface of each of the grooves. The gate dielectric layer 12 may be formed by one or more of a thermal oxidation process, a chemical vapor deposition process, and an atomic layer deposition process. A gate conductive layer may be stacked to fill the grooves, and the gate conductive layer may be etched-back to form the word lines WL. A dielectric layer such as a silicon nitride layer may be stacked on the substrate 1 so as to fill the grooves, and then the dielectric layer may be etched to form word-line capping patterns 14 on corresponding word lines WL.

The word-line capping patterns 14 and the device isolation pattern STI may be used as a mask to implant the active sections ACT with dopants to form first and second impurity regions 3a and 3b. A dielectric layer and a first polysilicon layer may be sequentially formed on a front surface of the substrate 1. The first polysilicon layer may be patterned to form a polysilicon mask pattern, and the polysilicon mask pattern may be used to etch the device isolation pattern STI, the substrate 1, and the word-line capping patterns 14 to simultaneously form a first recess R1 and an interlayer dielectric pattern 30. The first recess R1 may expose the first impurity regions 3a.

A bit line BL, which includes a bit-line polysilicon pattern 32, a bit-line diffusion barrier pattern 34, and a bit-line wiring pattern 36, may be formed on the front surface of the substrate 1. A bit-line contact DC and a bit-line capping pattern 38 may be formed on the front surface of the substrate 1. The etching process mentioned above may partially expose a top surface of the interlayer dielectric pattern 30, and may also partially expose an inner sidewall and a bottom surface of first recess R1.

A first spacer layer may be conformally formed on the front surface of the substrate 1. The first spacer layer may conformally cover the top surface of the interlayer dielectric pattern 30, and may also conformally cover the bottom surface and the inner sidewall of the first recess R1. A buried dielectric layer may be stacked on the front surface of the substrate 1 so as to fill the first recess R1, and then a first anisotropic etching process may be employed to form a first sub-spacer 21 while leaving a lower buried dielectric pattern 27 in the first recess R1.

A second spacer layer may be conformally stacked on the front surface of the substrate 1, and then a second anisotropic etching process may be employed to form a second sub-spacer 23 that covers a sidewall of the first sub-spacer 21. The second sub-spacer 23 may include a material having an etch selectivity with respect to the first sub-spacer 21. The second anisotropic etching process for forming the second sub-spacer 23 may expose the top surface of the interlayer dielectric pattern 30.

A third spacer layer may be conformally stacked on the front surface of the substrate 1, and then a third anisotropic etching process may be employed to form a third sub-spacer 25 that covers a sidewall of the second sub-spacer 23. The third anisotropic etching process for forming the third sub-spacer 25 may expose the top surface of the interlayer dielectric pattern 30. The first, second, and third sub-spacers 21, 23, and 25 may constitute a bit-line spacer BSP on a sidewall of the bit line BL.

An impurity-doped second polysilicon layer 70 may be stacked on the front surface of the substrate 1, thereby filling a space between the bit lines BL.

Referring to FIG. 4B, a planarization process may be accomplished by performing a first chemical mechanical polishing (CMP) process on top surfaces of the bit lines BL, the bit-line spacers BSP, and the second polysilicon layer 70. Therefore, preliminary storage node contacts 72 may be formed, and it may be possible to planarize top surfaces 38_s of the bit-line capping patterns 38, top surfaces BSP_s of the bit-line spacers BSP, and top surfaces 72_s of the preliminary storage node contacts 72. The top surfaces 38_s of the bit-line capping patterns 38 may be coplanar with the top surfaces BSP_s of the bit-line spacers BSP and the top surfaces 72_s of the preliminary storage node contacts 72. Although not shown, the first CMP process may reduce heights (levels) of the top surfaces 38_s and BSP_s of the bit-line capping patterns 38 and the bit-line spacers BSP, and thus it may be possible to reduce a step difference between a subsequently described data storage element DSP and a core/peripheral region of a semiconductor device.

Referring to FIG. 4C, the preliminary storage node contacts 72 may be etched to form storage node contacts BC and simultaneously to expose a sidewall of the third sub-spacer 25, the top surface BSP_s of the bit-line spacer BSP, and the top surface 38_s of the bit-line capping pattern 38. A storage node ohmic layer 40 may be formed on top surfaces of the storage node contacts BC. The storage node ohmic layer 40 may be formed of cobalt silicide. For example, after a cobalt layer is formed on the front surface of the substrate 1, the cobalt layer may be thermally treated to react with silicon of the storage node contact BC to form a cobalt silicide layer and then a non-reacted cobalt layer may be removed to form the storage node ohmic layer 40.

Referring to FIG. 4D, a first diffusion barrier layer 61m may be conformally formed on the front surface of the substrate 1. In some example embodiments, the storage node ohmic layer 40 and the first diffusion barrier layer 61m may be formed concurrently with each other. For example, a titanium (Ti) layer and a titanium nitride (TiN) layer may be conformally sequentially deposited to form the first diffusion barrier layer 61m on the top surface of the storage node contact BC. In this step, a temperature of the deposition process may cause Ti or TiN and silicon of the storage node contact BC to react with each other to form the storage node ohmic layer 40 formed of TiSi or TiSiN at an interface between the first diffusion barrier layer 61m and the storage node contact BC. The first diffusion barrier layer 61m may be formed by, for example, atomic layer deposition (ALD) or chemical vapor deposition (CVD).

The first diffusion barrier layer 61m may cover the bit-line capping patterns 38, the bit-line spacers BSP, and the storage node ohmic layer 40. The first diffusion barrier layer 61m may be formed having an uneven structure on a top surface 61m_s thereof. A first void V1 may be formed between the storage node contact BC and the top surface 61m_s of the first diffusion barrier layer 61m.

Referring to FIG. 4E, a second CMP process may be performed to planarize the top surfaces 61m_s, 38_s, and BSP_s of the first diffusion barrier layer 61m, the bit-line capping patterns 38, and the bit-line spacers BSP, thereby removing the first diffusion barrier layer 61m on the bit-line capping patterns 38 and the bit-line spacers BSP. Thus, a first sub-diffusion barrier pattern 61 may be formed to cover sidewalls of the bit-line spacers BSP. Atop surface 61_s of the first sub-diffusion barrier pattern 61 may be coplanar with the top surfaces 38_s of the bit-line capping patterns 38 and the top surfaces BSP_s of the bit-line spacers BSP.

The second CMP process may be a planarization process executed in advance to facilitate a fourth anisotropic etching process for node separation carried out in a step of FIG. 4I which will be discussed below. In this case, the first void V1 formed in FIG. 4D may lead to delamination or cutoff of the first sub-diffusion barrier pattern 61 that covers the sidewall of the third sub-spacer 25.

Referring to FIG. 4F, a second diffusion barrier layer 62m may be conformally formed on the front surface of the substrate 1. The second diffusion barrier layer 62m may be formed by, for example, atomic layer deposition (ALD) or chemical vapor deposition (CVD).

The second diffusion barrier layer 62m may cover the bit-line capping patterns 38, the bit-line spacers BSP, and the storage node ohmic layer 40. The second diffusion barrier layer 62m may cover a top surface and a sidewall of the first sub-diffusion barrier pattern 61. The second diffusion barrier layer 62m may be formed having an uneven structure on a top surface 62m_s thereof. When the first sub-diffusion barrier pattern 61 and the second diffusion barrier layer 62m include the same material, the first sub-diffusion barrier pattern 61 and the second diffusion barrier layer 62m may be formed integrally into a single unitary piece without any interface (e.g., any visible interface) therebetween. In this step, a second void V2 may be formed between the storage node contact BC and the top surface 62m_s of the second diffusion barrier layer 62m. The second void V2 may be formed to have a size less than that of the first void V1 depicted in FIG. 4D.

As the second diffusion barrier layer 62m is additionally formed on the first sub-diffusion barrier pattern 61, a diffusion barrier pattern 60 which will be discussed below may be formed relatively thick on the sidewall of the bit-line spacer BSP, and the second void V2 may have a reduced size. Therefore, it may be possible to reduce or prevent process failure of delamination or cutoff of the diffusion barrier pattern 60. Thus, reliability of a semiconductor device may be improved.

Referring to FIG. 4G, a third CMP process may be performed to planarize the top surface 62m_s of the second diffusion barrier layer 62m. The top surface 62m_s of the second diffusion barrier layer 62m may be located at a vertical level higher than that of the top surfaces 38_s of the bit-line capping patterns 38 and that of the top surfaces BSP_s of the bit-line spacers BSP. The present inventive concepts, however, are not limited thereto, and the third CMP process may be omitted.

Referring to FIG. 4H, a landing pad layer LP_m may be formed on the front surface of the substrate 1. The landing pad layer LP_m may be formed by sputtering, physical vapor deposition (PVD), or chemical vapor deposition (CVD). A fourth CMP process may be performed to planarize the landing pad layer LP_m. On the landing pad layer LP_m, mask patterns MK may be formed to limit planar shapes of landing pads LP which will be discussed below. The mask patterns MK may be formed to vertically overlap the bit lines BL and the storage node contacts BC.

Referring to FIG. 4I, the mask patterns MK may be used as an etching mask to perform a fourth anisotropic etching process to partially remove the landing pad layer LP_m, the first sub-diffusion barrier pattern 61, and the second diffusion barrier layer 62m, thereby forming landing pads LP and a diffusion barrier pattern 60 and also forming second recesses R2 that expose the diffusion barrier pattern 60. The diffusion barrier pattern 60 may include a first sub-diffusion barrier pattern 61 and a second sub-diffusion barrier pattern 62. When the first sub-diffusion barrier pattern 61 and the second sub-diffusion barrier pattern 62 are formed of the same material, the first sub-diffusion barrier pattern 61 and the second sub-diffusion barrier pattern 62 may be integrally connected into a single unitary piece without any interface (e.g., any visible interface), and this case is illustrated in FIGS. 3A and 3B.

In the fourth anisotropic etching process, the bit-line capping patterns 38 and the bit-line spacers BSP may also be partially removed to expose top surfaces and upper sidewalls thereof. The fourth anisotropic etching process may accomplish node separation on the substrate 1.

Referring back to FIG. 2, the mask patterns MK may be removed. The second recesses R2 may be filled with a dielectric material to form a landing pad isolation pattern 50. Afterwards, a data storage element DSP may be formed on the landing pads LP. Accordingly, a semiconductor device may be fabricated as shown in FIGS. 1 and 2.

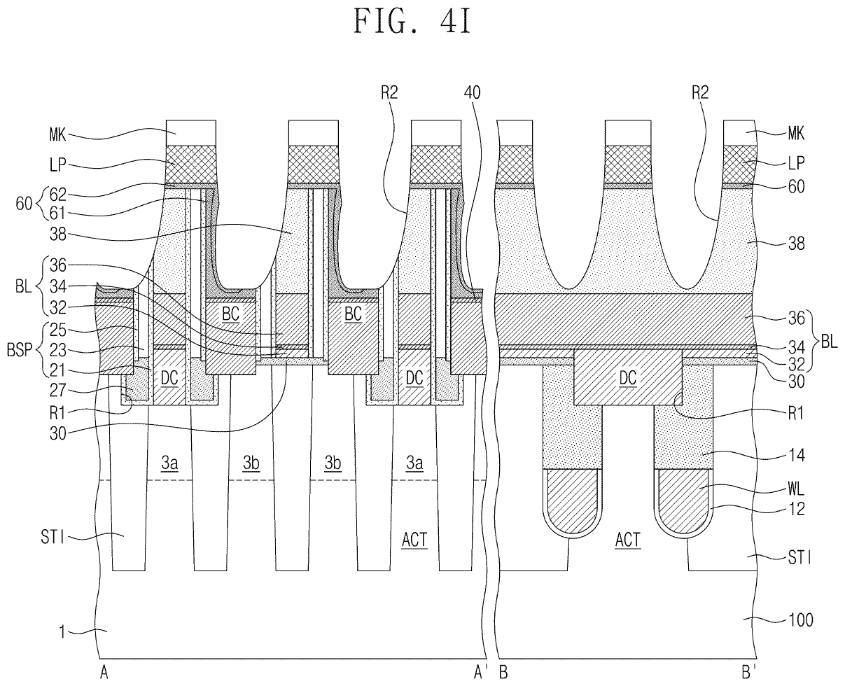

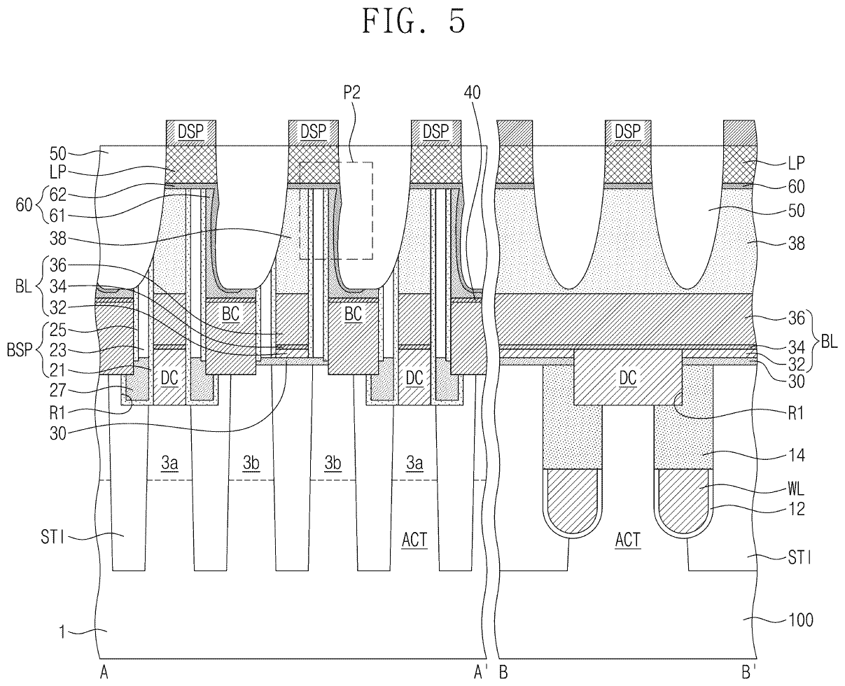

FIG. 5 illustrates a cross-sectional view taken along lines A-A′ and B-B′ of FIG. 1, according to an example embodiment. FIG. 6 illustrates an enlarged view showing section P2 of FIG. 5.

Referring to FIGS. 1, 5, and 6, in some example embodiments, the diffusion barrier pattern 60 may include first and second sub-diffusion barrier patterns 61 and 62. The first sub-diffusion barrier pattern 61 may cover a top surface of the storage node ohmic layer 40 and a sidewall of the bit-line spacer BSP. The first sub-diffusion barrier pattern 61 may have a flat top surface 61_s. The top surface 61_s of the first sub-diffusion barrier pattern 61 may be coplanar with a top surface BSP_s of the bit-line spacer BSP and a top surface 38_s of the bit-line capping pattern 38.

The second sub-diffusion barrier pattern 62 may cover a sidewall and a portion of a bottom surface of the first sub-diffusion barrier pattern 61. The second sub-diffusion barrier pattern 62 may extend to cover the top surface 61_s of the first sub-diffusion barrier pattern 61, the top surface BSP_s of the bit-line spacer BSP, and the top surface 38_s of the bit-line capping pattern 38. The second sub-diffusion barrier pattern 62 may have a flat top surface 62_s. In some example embodiments, differently from that shown, the second sub-diffusion barrier pattern 62 may have an uneven structure on the top surface 62_s.

The first sub-diffusion barrier pattern 61 and the second sub-diffusion barrier pattern 62 may include different materials from each other. In this case, an interface may be present between the first sub-diffusion barrier pattern 61 and the second sub-diffusion barrier pattern 62. The second sub-diffusion barrier pattern 62 may be additionally disposed on the first sub-diffusion barrier pattern 61, and thus cutoff failure of the diffusion barrier pattern 60 occurring on the sidewall of the bit-line spacer BSP may be reduced or prevented. Therefore, a semiconductor device may be free of malfunction and may have improved reliability. Other configurations may be identical or similar to those discussed above with reference to FIGS. 1, 2, and 3A.

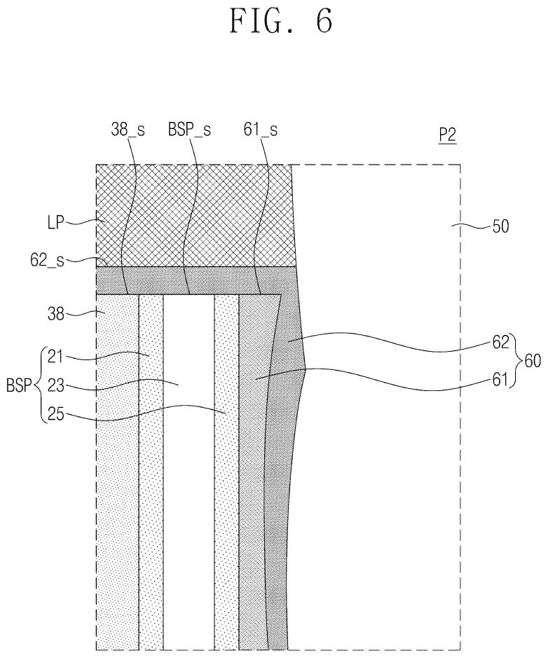

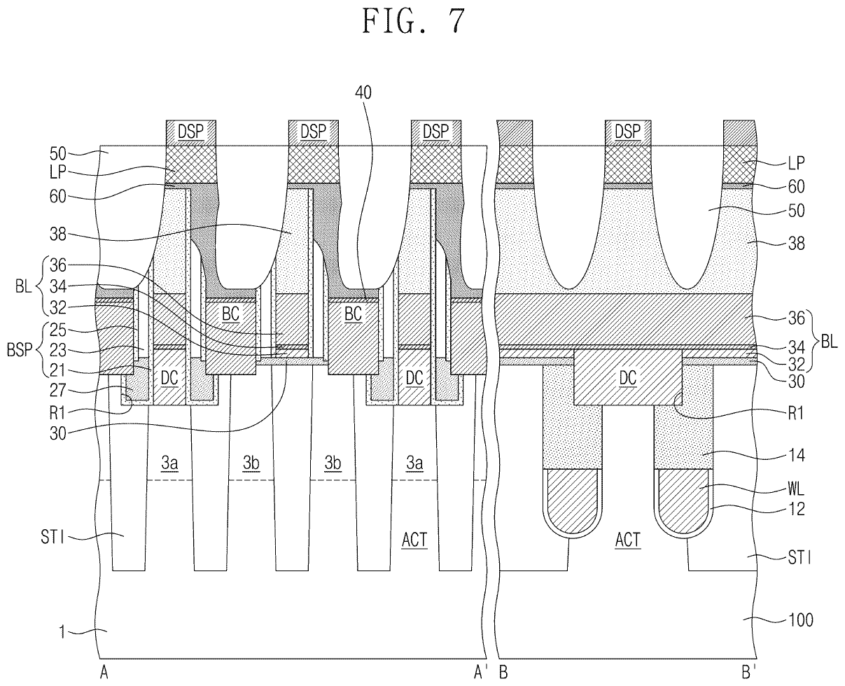

FIG. 7 illustrates a cross-sectional view taken along lines A-A′ and B-B′ of FIG. 1, according to an example embodiment.

Referring to FIGS. 1 and 7, in some example embodiments, the bit-line spacer BSP may include first, second, and third sub-spacers 21, 23, and 25 that are sequentially disposed from a sidewall of the bit line BL. The first sub-spacer 21 may cover a sidewall of the bit line BL and a sidewall of the bit-line capping pattern 38. The first sub-spacer 21 may extend to cover an inner sidewall and a bottom surface of the first recess R1. The second sub-spacer 23 may cover a lower sidewall of the first sub-spacer 21 and expose an upper sidewall of the first sub-spacer 21. The first sub-spacer 21 may extend to cover a bottom surface of the second sub-spacer 23. The third sub-spacer 25 may cover a sidewall of the second sub-spacer 23. Differently from that shown, a lower end of the first sub-spacer 21 may be in contact with the third sub-spacer 25.

As shown in the cross-sectional view taken along line A-A′ of FIG. 7, an upper end of the first sub-spacer 21 may be higher than those of the second and third sub-spacers 23 and 25. An upper sidewall of the first sub-spacer 21 may not be covered with the second and third sub-spacers 23 and 25. The second sub-spacer 23 may include a different material from that of the first sub-spacer 21 and that of the third sub-spacer 25. For example, the first sub-spacer 21 and the third sub-spacer 25 may include silicon nitride. The second sub-spacer 23 may include silicon oxide. In some example embodiments, the second subs-spacer 23 may be an air gap.

Although not shown, a fourth spacer may be additionally disposed to cover an upper sidewall of the first sub-spacer 21 and a top surface of the second sub-spacer 23. The fourth sub-spacer may serve to reinforce a thin upper portion of the first sub-spacer 21.

The diffusion barrier pattern 60 may cover a top surface of the storage node ohmic layer 40 and a sidewall of the third sub-spacer 25. The diffusion barrier pattern 60 may cover upper sidewalls of the first and second sub-spacers 21 and 23. The diffusion barrier pattern 60 may extend to cover a top surface of the bit-line capping pattern 38. Other configurations may be identical or similar to those discussed with reference to FIGS. 1, 2, 3A, and 3B.

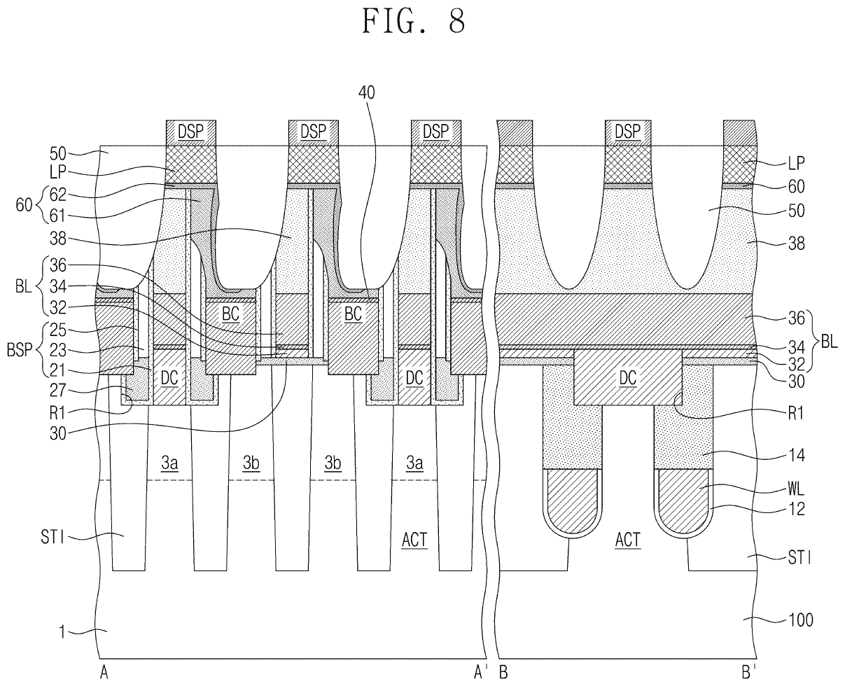

FIG. 8 illustrates a cross-sectional view taken along lines A-A′ and B-B′ of FIG. 1, according to an example embodiment.

Referring to FIGS. 1, 7, and 8, a semiconductor device of FIG. 8 may have a structure in which the diffusion barrier pattern 60 includes first and second sub-diffusion barrier patterns 61 and 62 in the structure of FIG. 7. The first sub-diffusion barrier pattern 61 may cover a top surface of the storage node ohmic layer 40 and a sidewall of the third sub-spacer 25. The first sub-diffusion barrier pattern 61 may cover upper sidewalls of the first and second sub-spacers 21 and 23. The first sub-diffusion barrier pattern 61 may have a flat top surface. The top surface of the first sub-diffusion barrier pattern 61 may be coplanar with a top surface of the bit-line spacer BSP and a top surface of the bit-line capping pattern 38.

The second sub-diffusion barrier pattern 62 may cover a sidewall and a portion of a bottom surface of the first sub-diffusion barrier pattern 61 that is in contact with the storage node ohmic layer 40. The second sub-diffusion barrier pattern 62 may cover a top surface of the first sub-diffusion barrier pattern 61 and a top surface of the bit-line capping pattern 38.

The first sub-diffusion barrier pattern 61 and the second sub-diffusion barrier pattern 62 may include different materials from each other. In this case, an interface may be present between the first sub-diffusion barrier pattern 61 and the second sub-diffusion barrier pattern 62. Other configurations may be identical or similar to those discussed with reference to FIGS. 1, 2, 3A, 3B, and 7.

In a semiconductor device according to the present inventive concepts, a diffusion barrier pattern that connects a landing pad to a storage node contact may be formed relatively thick on a sidewall of a bit-line spacer. Thus, cutoff failure of the diffusion barrier pattern occurring on the sidewall of the bit-line spacer may be reduced or prevented. Therefore, malfunction of the semiconductor device may be reduced or prevented and thus reliability of the semiconductor device may be improved.

In a method of fabricating a semiconductor device according to the present inventive concepts, a second sub-diffusion barrier layer may be formed on a first sub-diffusion barrier pattern, and thus it may be possible to reduce a size of void generated between bit-line spacers and to increase a thickness of a diffusion barrier pattern compared to a case where only the first sub-diffusion barrier pattern is formed. Thus, cutoff failure of the diffusion barrier pattern occurring on a sidewall of the bit-line spacer may be reduced or prevented. Thus, reliability of the semiconductor device may be improved.

Although some example embodiments of inventive concepts have been discussed with reference to accompanying figures, it will be understood that various changes in form and details may be made therein without departing from the spirit and scope of the present inventive concepts. It will be apparent to those skilled in the art that various substitution, modifications, and changes may be thereto without departing from the scope and spirit of the present inventive concepts.

What is claimed is:

1. A semiconductor device, comprising:
a plurality of device isolation patterns in a substrate, the device isolation patterns defining a plurality of active sections, the active sections extending in a first direction;
a first impurity region on a central region of each of the active sections;
a plurality of second impurity regions on edges of each of the active sections;
a bit line connected to the first impurity region, the bit line running in a second direction across the active sections, the second direction intersecting the first direction;
a bit-line capping pattern on the bit line;
a storage node contact in contact with each of the second impurity regions;
a diffusion barrier pattern covering a top surface of the bit-line capping pattern and a top surface of the storage node contact; and
a landing pad on the diffusion barrier pattern,
wherein a top surface of the diffusion barrier pattern is flat.

2. The device of claim 1, further comprising:
a bit-line spacer covering a sidewall of the bit line and a sidewall of the bit-line capping pattern,
wherein a top surface of the bit-line spacer is flat, and
wherein the top surface of the bit-line capping pattern is coplanar with the top surface of the bit-line spacer.

3. The device of claim 2, wherein
the diffusion barrier pattern includes a first part and a second part,
the first part covers the top surface of the bit-line spacer and has a first thickness, and
the second part covers an upper sidewall of the bit-line spacer and has a second thickness greater than the first thickness.

4. The device of claim 3, wherein
the diffusion barrier pattern further includes a third part beneath the second part, the third part covering a sidewall of the bit-line spacer, and
the third part has a third thickness greater than the first thickness and less than the second thickness.

5. The device of claim 3, wherein the diffusion barrier pattern has the first thickness on the bit-line capping pattern.

6. The device of claim 1, wherein a lower end of the landing pad is at a level higher than a level of the top surface of the bit-line capping pattern.

7. The device of claim 1, wherein
the landing pad comprises a plurality of landing pads,
the storage node contact comprises a plurality of storage node contacts, and
the device further comprises a landing pad isolation pattern on the storage node contacts, respectively, and between adjacent pairs of the landing pads, respectively.

8. The device of claim 1, wherein the diffusion barrier pattern includes:
a first sub-diffusion barrier pattern covering a sidewall of the bit-line capping pattern; and
a second sub-diffusion barrier pattern covering the top surface of the bit-line capping pattern and a sidewall of the first sub-diffusion barrier pattern,
wherein the first sub-diffusion barrier pattern and the second sub-diffusion barrier pattern include different materials from each other.

9. The device of claim 1, further comprising:
a bit-line spacer covering a sidewall of the bit line and a sidewall of the bit-line capping pattern,
wherein the bit-line spacer includes
a first sub-spacer covering the sidewall of the bit line
a second sub-spacer covering a lower sidewall of the first sub-spacer and exposing an upper sidewall of the first sub-spacer and
a third sub-spacer covering a sidewall of the second sub-spacer.

10. A semiconductor device, comprising:
a plurality of device isolation patterns in a substrate, the device isolation patterns defining a plurality of active sections, the active sections extending in a first direction;
a plurality of word lines in the substrate, the word lines running in a second direction across the active sections, the second direction intersecting the first direction;
a first impurity region on a central region of each of the active sections;
a plurality of second impurity regions on edges of each of the active sections;
a bit line connected to the first impurity region, the bit line running in the second direction across the word lines;
a bit-line capping pattern on the bit line;
a bit-line spacer covering a sidewall of the bit line and a sidewall of the bit-line capping pattern;
a storage node contact in contact with each of the second impurity regions;
a diffusion barrier pattern covering a top surface of the bit-line capping pattern, a top surface of the storage node contact, and a top surface and a sidewall of the bit-line spacer; and
a landing pad on the diffusion barrier pattern,
wherein the diffusion barrier pattern has a first thickness on the top surface of the bit-line capping pattern and a second thickness on the sidewall of the bit-line capping pattern, the second thickness being greater than the first thickness.

11. The device of claim 10, wherein
the top surface of the bit-line capping pattern is flat,
the top surface of the bit-line spacer is flat, and
wherein the top surface of the bit-line capping pattern is coplanar with the top surface of the bit-line spacer.

12. The device of claim 10, wherein the diffusion barrier pattern has the first thickness on the top surface of the bit-line spacer.

13. The device of claim 10, wherein the diffusion barrier pattern includes:
a first part on an upper sidewall of the bit-line spacer; and
a second part beneath the first part and having the second thickness,
wherein the first part has a third thickness greater than the second thickness.

14. The device of claim 10, wherein a portion of the diffusion barrier pattern that is on the bit-line capping pattern has a flat top surface.

15. The device of claim 10, wherein a top surface of the diffusion barrier pattern on the bit-line capping pattern has an uneven structure.

16. The device of claim 10, wherein the bit-line spacer includes:
a first sub-spacer covering the sidewall of the bit line;
a second sub-spacer covering a lower sidewall of the first sub-spacer and exposing an upper sidewall of the first sub-spacer; and
a third sub-spacer covering a sidewall of the second sub-spacer.

17. A semiconductor device, comprising:
a plurality of device isolation patterns in a substrate, the device isolation patterns defining a plurality of active sections, the active sections extending in a first direction;
a first impurity region on a central region of each of the active sections;
a plurality of second impurity regions on edges of each of the active sections;
a bit line connected to the first impurity region, the bit line running in a second direction across the active sections, the second direction intersecting the first direction;
a bit-line capping pattern on the bit line;
a bit-line spacer covering a sidewall of the bit line and a sidewall of the bit-line capping pattern;
a storage node contact in contact with each of the second impurity regions;
a first sub-diffusion barrier pattern covering a top surface of the storage node contact and a sidewall of the bit-line spacer;
a second sub-diffusion barrier pattern covering the first sub-diffusion barrier pattern and a top surface of the bit-line capping pattern; and
a landing pad on the first and second sub-diffusion barrier patterns.

18. The device of claim 17, wherein a top surface of the first sub-diffusion barrier pattern, the top surface of the bit-line capping pattern, and a top surface of the bit-line spacer are flat and coplanar with each other.

19. The device of claim 17, wherein the second sub-diffusion barrier pattern extends to cover the top surface of the bit-line capping pattern, a top surface of the bit-line spacer, and a top surface of the first sub-diffusion barrier pattern.

20. The device of claim 17, wherein the first sub-diffusion barrier pattern and the second sub-diffusion barrier pattern include different materials from each other.
